(19) United States
(12) Patent Application Publication
(10) Pub. No.: US 2026/0244100 A1
(43) Pub. Date: Aug. 20, 2026

(54) PHOTOSENSITIVE ELEMENT, AND METHOD FOR FORMING RESIST PATTERN

(71) Applicant: Resonac Corporation, Tokyo (JP)

(72) Inventor: Naoki HIRAMATSU, Tokyo (JP)

(21) Appl. No.: 18/859,104

(22) PCT Filed: Jun. 5, 2023
(86) PCT No.: PCT/JP2023/020769

§ 371 Date: Oct. 22, 2024

(30) Foreign Application Priority Data
Jun. 6, 2022 (WO) PCT/JP2022/022830

(51) Int. Cl. G03F 7/033; G03F 7/00; G03F 7/031; G03F 7/105

(52) U.S. Cl. CPC G03F 7/033; G03F 7/0005; G03F 7/031; G03F 7/105

(57) ABSTRACT

A photosensitive element, including: a support; and a photosensitive layer on the support by using a photosensitive resin composition containing a binder polymer, a photopolymerizable compound, a photopolymerization initiator, and a coumarin-based sensitizer, in which a thickness of the photosensitive layer is 30 μm or more.

### TECHNICAL FIELD

The present disclosure relates to a photosensitive element and a method for forming a resist pattern.

### BACKGROUND ART

In the field of producing a semiconductor integrated circuit (LSI), a wiring board, or the like, a photosensitive material is used as a resist material for producing a conductor pattern. For example, in the production of the wiring board, a resist pattern is formed by using a photosensitive resin composition, and then, a conductor pattern, a metal post, and the like are formed by a plating treatment. Specifically, it is possible to produce the wiring board including the conductor pattern, the metal post, and the like by (1) forming a photosensitive layer on a base material by using the photosensitive resin composition, (2) exposing the photosensitive layer through a predetermined mask pattern, (3) selectively removing (peeling) a portion for forming the conductor pattern, the metal post, and the like by a developing treatment to form the resist pattern, and (4) forming a conductor layer such as copper in the removed portion by a plating treatment, and then, removing the resist pattern (for example, refer to Patent Literature 1 described below).

### CITATION LIST

### Patent Literature

Patent Literature 1: Japanese Unexamined Patent Publication No. 2000-356852

### SUMMARY OF INVENTION

### Technical Problem

Recently, in an electronic part such as an inductor, it has been considered to form a conductor pattern including a conductor layer with a high aspect ratio in a thick layer state. Such a conductor pattern, for example, can be obtained by irradiating a photosensitive layer with light, and then, removing an unexposed portion to form a space portion, and forming a conductor layer in the space portion. Therefore, a photosensitive element for obtaining a photosensitive layer as a thick film is required to obtain a resist pattern including a space portion with a high aspect ratio.

In addition, not only a coil (a conductive coil) of an inductor (such as a power inductor), but also a copper pillar and the like configuring a connecting portion of a semiconductor chip are required to have a high aspect ratio in accordance with an increase in the number of terminals due to the densification of the semiconductor chip, and there is a demand for a photosensitive element including a photosensitive layer capable of forming a coil-shaped resist pattern for forming a coil with a high aspect ratio, a via hole pattern for forming a copper pillar, and the like with a high resolution. In addition, the photosensitive layer is also required to have a high sensitivity to an active ray.

An object of the present disclosure is to provide a photosensitive element including a photosensitive layer that has a high sensitivity to an active ray and is capable of obtaining a resist pattern including a space portion with a high aspect ratio, and a method for forming a resist pattern using the same.

### Solution to Problem

In order to attain the object described above, the present disclosure provides a photosensitive element and a method for forming a resist pattern described below.

[1] A photosensitive element, including: a support; and a photosensitive layer formed on the support by using a photosensitive resin composition containing a binder polymer, a photopolymerizable compound, a photopolymerization initiator, and a coumarin-based sensitizer, in which a thickness of the photosensitive layer is 30 μm or more.

[2] The photosensitive element according to [1] described above, in which the binder polymer has benzyl (meth)acrylate as a monomer unit.

[3] The photosensitive element according to [2] described above, in which in the binder polymer, a content of the benzyl (meth)acrylate is 10 to 60% by mass, on the basis of a total amount of the monomer unit configuring the binder polymer.

[4] The photosensitive element according to any of [1] to [3] described above, in which the binder polymer has styrene as a monomer unit.

[5] The photosensitive element according to [4] described above, in which in the binder polymer, a content of the styrene is 10 to 50% by mass, on the basis of a total amount of the monomer unit configuring the binder polymer.

[6] The photosensitive element according to any of [1] to [5] described above, in which the binder polymer has alkyl (meth)acrylate as a monomer unit.

[7] The photosensitive element according to [6] described above, in which in the binder polymer, a content of the alkyl (meth)acrylate is 5 to 40% by mass, on the basis of a total amount of the monomer unit configuring the binder polymer.

[8] The photosensitive element according to any of [1] to [7] described above, in which the binder polymer has a (meth)acrylic acid as a monomer unit.

[9] The photosensitive element according to [8] described above, in which in the binder polymer, a content of the (meth)acrylic acid is 10 to 40% by mass, on the basis of a total amount of the monomer unit configuring the binder polymer.

[10] The photosensitive element according to any of [1] to [9] described above, in which a content of the coumarin-based sensitizer is 0.01 to 0.3 parts by mass, with respect to 100 parts by mass of a total amount of the binder polymer and the photopolymerizable compound.

[11] The photosensitive element according to any of [1] to [10] described above, in which the photopolymerizable compound includes (meth)acrylate having one polymerizable ethylenically unsaturated bond in molecules.

[12] The photosensitive element according to [11] described above, in which a content of the (meth)acrylate having one polymerizable ethylenically unsaturated bond in the molecules is 1 to 30% by mass, on the basis of a total amount of the photopolymerizable compound.

[13] The photosensitive element according to any of [1] to [12] described above, in which the photopolymerizable compound includes urethane (meth)acrylate.

[14] The photosensitive element according to any of [1] to [13] described above, in which the photopolymerization initiator includes at least one type selected from the group consisting of a hexaaryl biimidazole derivative and an acridine compound.

[15] The photosensitive element according to any of [1] to [14] described above, in which the thickness of the photosensitive layer is 75 μm or more.

[16] The photosensitive element according to any of [1] to [14] described above, in which the thickness of the photosensitive layer is greater than 100 μm.

[17] The photosensitive element according to any of [1] to [16] described above, in which the photosensitive element is for forming a resist pattern including a space portion with an aspect ratio of 1.3 or more.

[18] The photosensitive element according to any of [1] to [17] described above, in which the photosensitive element is for forming a conductive coil of an inductor.

[19] The photosensitive element according to any of [1] to [17] described above, in which the photosensitive element is for forming a copper pillar for semiconductor connection.

[20] A method for forming a resist pattern, including: a step of providing a photosensitive layer on a base material by using the photosensitive element according to any of [1] to [19] described above; a step of irradiating at least a part of the photosensitive layer with an active ray to form a photocured portion; and a step of removing at least a part of the photosensitive layer other than the photocured portion to form a resist pattern.

[21] The method for forming a resist pattern according to [20] described above, in which the resist pattern includes a space portion with an aspect ratio of 1.3 or more.

### Advantageous Effects of Invention

According to the present disclosure, it is possible to provide the photosensitive element including the photosensitive layer that has a high sensitivity to the active ray and is capable of obtaining the resist pattern including the space portion with a high aspect ratio, and the method for forming a resist pattern using the same. According to the photosensitive element of the present disclosure, since it is possible to obtain the resist pattern including the space portion with a high aspect ratio, it is possible to form a coil-shaped (spiral) resist pattern and a via hole pattern with a high resolution, which enables a coil of an inductor, and a copper pillar and the like configuring a connecting portion of a semiconductor device to be formed with a high aspect ratio.

### BRIEF DESCRIPTION OF DRAWINGS

FIG. 1 is a schematic cross-sectional view illustrating a photosensitive element according to one embodiment of the present disclosure.

FIG. 2 is a schematic cross-sectional view illustrating an example of a method for producing a stacked body.

FIG. 3 is an electron microscopic picture of a square coil pattern formed by using a photosensitive element of Example 2.

### DESCRIPTION OF EMBODIMENTS

Hereinafter, an embodiment of the present disclosure will be described in detail.

In this specification, a numerical range of “A or more” indicates A and a range greater than A. A numerical range of “A or less” indicates A and a range less than A. In numerical ranges described in stages in this specification, the upper limit value or the lower limit value of a numerical range in a certain stage can be arbitrarily combined with the upper limit value or the lower limit value of a numerical range in the other stage. In the numerical range described in this specification, the upper limit value or the lower limit value of the numerical range may be replaced with values described in Examples. “A or B” may include either A or B, or may include both thereof. Only one type of materials exemplified in this specification can be used alone, or two or more types thereof can be used in combination, unless otherwise specified. In a case where there are a plurality of substances corresponding to each component in a composition, the content of each component in the composition indicates the total amount of the plurality of substances in the composition, unless otherwise specified. The term “layer” includes not only a structure in which a layer is formed on the entire surface but also a structure in which a layer is formed on a part of the surface when observed as a plan view. The term “step” includes not only an independent step but also a step that is not explicitly distinguishable from other steps insofar as a desired function of the step is attained. “(Meth)acrylate” indicates at least one of acrylate and methacrylate corresponding thereto. The same also applies to other similar expressions such as a “(meth)acrylic acid”. An “alkyl group” may be a linear, branched, or cyclic alkyl group, unless otherwise specified. The content of the monomer unit of a (meth)acrylic acid compound (such as alkyl (meth)acrylate) indicates the total amount of the content of the monomer unit of an acrylic acid compound and the content of the monomer unit of a methacrylic acid compound.

In this specification, in a case where there are a plurality of substances corresponding to each component in a composition, the amount of each component in the composition indicates the total amount of the plurality of substances in the composition, unless otherwise specified. In this specification, a “solid content” indicates a non-volatile content excluding a volatile substance (water, a solvent, or the like) in a photosensitive resin composition. That is, the “solid content” indicates a component other than the solvent, which remains without being volatilized in the drying of the photosensitive resin composition described below, and also includes a component in the form of a liquid, syrup, or a wax at a room temperature (25° C.).

### [Photosensitive Element]

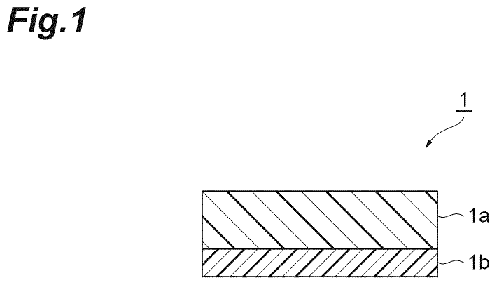

A photosensitive element according to this embodiment includes a support, and a photosensitive layer provided on the support. FIG. 1 is a schematic cross-sectional view illustrating a photosensitive element according to one embodiment of the present disclosure. A photosensitive element 1 illustrated in FIG. 1 includes a photosensitive layer 1a, and a support (a support film) 1b supporting the photosensitive layer 1a. The photosensitive layer is a layer formed by using a photosensitive resin composition containing a binder polymer (A) (hereinafter, referred to as a “component (A)” in some cases), a photopolymerizable compound (B) (hereinafter, referred to as a “component (B)” in some cases), a photopolymerization initiator (C) (hereinafter, referred to as a “component (C)” in some cases), and a coumarin-based sensitizer (D) (hereinafter, referred to as a “component (D)” in some cases). The thickness of the photosensitive layer is 30 μm or more.

In the photosensitive element according to this embodiment, the photosensitive layer is a thick layer of 30 μm or more. In the related art, in a case where the photosensitive layer is thick, since it is difficult for light to penetrate to the bottom portion of the photosensitive layer, there is a tendency that it is difficult to form a space portion with a high aspect ratio, and obtain a high resolution. In addition, in a case where the photosensitive layer is thick, there is a tendency that it is difficult to make a high sensitivity and a high resolution compatible. Then, a photosensitive element of the related art is not necessarily suitable for forming a coil-shaped resist pattern and a via hole pattern. In contrast, according to the photosensitive element of this embodiment, by using the components (A) to (D) described above for the photosensitive layer, it is possible to form a resist pattern including a space portion with a high aspect ratio while having a high sensitivity to an active ray, and form a coil-shaped resist pattern and a via hole pattern with a high resolution.

The photosensitive element according to this embodiment is suitable for forming a resist pattern including a space portion with an aspect ratio of 1.3 or more. The resist pattern with a high aspect ratio can be used for obtaining a conductor pattern, a metal post, and the like with a high aspect ratio. The photosensitive element according to this embodiment can be preferably used for producing an electronic part such as an inductor (for example, an electronic circuit board) and a semiconductor device, and for example, can be particularly preferably used for forming a conductive coil of an inductor (such as a power inductor), forming a copper pillar for semiconductor connection (forming a via hole pattern for forming a copper pillar), and the like.

### <Support>

Examples of the support include a polyester film such as a polyethylene terephthalate (PET) film, a polybutylene terephthalate (PBT) film, and a polyethylene-2,6-naphthalate (PEN) film; and a polyolefin film such as a polypropylene film and a polyethylene film.

The haze of the support may be 0.01 to 5.0%, 0.01 to 1.5%, 0.01 to 1.0%, or 0.01 to 0.5%. The haze can be measured by using a commercially available haze meter (a turbidimeter), on the basis of a method defined in JIS K7105. The haze, for example, can be measured with a commercially available turbidimeter such as NDH-5000 (manufactured by NIPPON DENSHOKU INDUSTRIES CO., LTD., Product Name).

The thickness of the support may be 1 to 200 μm, 1 to 100 μm, 1 to 60 μm, 5 to 60 μm, 10 to 60 μm, 10 to 50 μm, 10 to 40 μm, 10 to 30 μm, or 10 to 25 μm. By setting the thickness of the support to be 1 μm or more, it is easy to prevent the support from being ruptured when peeling the support. By setting the thickness of the support to be 200 μm or less, it is easy to obtain economic benefits.

### <Photosensitive Layer>

The photosensitive layer is a layer formed by using the photosensitive resin composition. The photosensitive resin composition contains the components (A) to (D) described above. Hereinafter, each component of the photosensitive resin composition will be described.

### (Component (A): Binder Polymer)

The photosensitive resin composition contains the binder polymer as the component (A). The component (A) may have a polymerizable monomer as a monomer unit (a structural unit), and for example, can be obtained by the radical polymerization of the polymerizable monomer. Examples of the polymerizable monomer include alkyl (meth)acrylate, benzyl (meth)acrylate, tetrahydrofurfuryl (meth)acrylate, dimethyl aminoethyl (meth)acrylate, diethyl aminoethyl (meth)acrylate, glycidyl (meth)acrylate, 2,2,2-trifluoroethyl (meth)acrylate, 2,2,3,3-tetrafluoropropyl (meth)acrylate, a (meth)acrylic acid, an α-bromo(meth)acrylic acid, an α-chloro(meth)acrylic acid, a β-furyl (meth)acrylate, β-styryl (meth)acrylate, acrylamide (such as diacetone (meth)acrylamide), (meth)acrylonitrile, a styrene compound (styrene or a styrene derivative), ethers of vinyl alcohol (such as vinyl-n-butyl ether), a maleic acid, a maleic anhydride, maleic acid monoester (such as monomethyl maleate, monoethyl maleate, and monoisopropyl maleate), a fumaric acid, a cinnamic acid, an α-cyanocinnamic acid, an itaconic acid, a crotonic acid, and a propiolic acid. The photosensitive resin composition may not contain a binder polymer having an aromatic ring as the component (A).

The component (A), from the viewpoint of easily obtaining the resist pattern including the space portion with a high aspect ratio, may have a (meth)acrylic acid as the monomer unit. The content of the (meth)acrylic acid in the component (A), from the viewpoint of easily obtaining the resist pattern including the space portion with a high aspect ratio, may be in the following range, on the basis of the total amount of the monomer unit configuring the component (A). The content of the (meth)acrylic acid may be 5% by mass or more, 10% by mass or more, 15% by mass or more, 20% by mass or more, 25% by mass or more, or 30% by mass or more. The content of the (meth)acrylic acid may be 60% by mass or less, 50% by mass or less, 45% by mass or less, 40% by mass or less, 35% by mass or less, or 30% by mass or less. From the above viewpoint, the content of the (meth)acrylic acid may be 5 to 60% by mass, or may be 10 to 40% by mass.

The component (A), from the viewpoint of easily obtaining the resist pattern including the space portion with a high aspect ratio, may have alkyl (meth)acrylate as the monomer unit. The content of the alkyl (meth)acrylate in the component (A), from the viewpoint of easily obtaining the resist pattern including the space portion with a high aspect ratio, may be in the following range, on the basis of the total amount of the monomer unit configuring the component (A). The content of the alkyl (meth)acrylate may be 5% by mass or more, 10% by mass or more, 15% by mass or more, 20% by mass or more, 25% by mass or more, 30% by mass or more, or 35% by mass or more. The content of the alkyl (meth)acrylate may be 60% by mass or less, 50% by mass or less, 45% by mass or less, 40% by mass or less, or 35% by mass or less. From the above viewpoint, the content of the alkyl (meth)acrylate may be 5 to 60% by mass, or may be 5 to 40% by mass.

An alkyl group of the alkyl (meth)acrylate may have a substituent. Examples of the substituent include a hydroxy group, a carboxy group, a carboxylate group, an alkoxy group, an amino group, a halogeno group, and a glycidyl group.

The component (A), from the viewpoint of easily obtaining the resist pattern including the space portion with a high aspect ratio, may have styrene as the monomer unit. The content of the styrene in the component (A), from the viewpoint of easily obtaining the resist pattern including the space portion with a high aspect ratio, may be in the following range, on the basis of the total amount of the monomer unit configuring the component (A). The content of the styrene may be 5% by mass or more, 10% by mass or more, 15% by mass or more, 20% by mass or more, 25% by mass or more, 30% by mass or more, or 35% by mass or more. The content of the styrene may be 60% by mass or less, 50% by mass or less, 45% by mass or less, 40% by mass or less, or 35% by mass or less. From the above viewpoint, the content of the styrene may be 5 to 60% by mass, or may be 10 to 50% by mass.

The component (A), from the viewpoint of easily obtaining the resist pattern including the space portion with a high aspect ratio and making both of the adhesiveness and the peelability of the resist pattern excellent, may have benzyl (meth)acrylate as the monomer unit. The content of the benzyl (meth)acrylate in the component (A), from the viewpoint of easily obtaining the resist pattern including the space portion with a high aspect ratio and making both of the adhesiveness and the peelability of the resist pattern excellent, may be in the following range, on the basis of the total amount of the monomer unit configuring the component (A). The content of the benzyl (meth)acrylate may be 5% by mass or more, 10% by mass or more, 15% by mass or more, 20% by mass or more, 25% by mass or more, 30% by mass or more, or 35% by mass or more. The content of the benzyl (meth)acrylate may be 60% by mass or less, 50% by mass or less, 45% by mass or less, 40% by mass or less, or 35% by mass or less. From the above viewpoint, the content of the benzyl (meth)acrylate may be 5 to 60% by mass, or may be 10 to 60% by mass.

The component (A), from the viewpoint of easily obtaining the resist pattern including the space portion with a high aspect ratio, may have at least one type selected from the group consisting of a (meth)acrylic acid, alkyl (meth)acrylate, styrene, and benzyl (meth)acrylate, as the monomer unit, or may have all of (meth)acrylic acid, alkyl (meth)acrylate, styrene, and benzyl (meth)acrylate, as the monomer unit.

The weight average molecular weight (Mw) of the component (A), from the viewpoint of easily obtaining the resist pattern including the space portion with a high aspect ratio, may be in the following range. The weight average molecular weight, from the viewpoint of easily obtaining excellent developer resistance, may be 10000 or more, 15000 or more, 20000 or more, 25000 or more, 30000 or more, 35000 or more, 40000 or more, 45000 or more, or 50000 or more. The weight average molecular weight, from the viewpoint of easily preventing a developing time from being lengthened, may be 300000 or less, 150000 or less, 100000 or less, 80000 or less, 60000 or less, 55000 or less, or 50000 or less. From the above viewpoint, the weight average molecular weight may be 10000 to 300000.

The degree of dispersion (Weight Average Molecular Weight/Number Average Molecular Weight) of the component (A), from the viewpoint of easily obtaining the resist pattern including the space portion with a high aspect ratio, may be in the following range. The degree of dispersion may be 1.0 or more, 1.5 or more, 1.8 or more, 2.0 or more, 2.1 or more, 2.2 or more, or 2.3 or more. The degree of dispersion may be 3.0 or less, 2.8 or less, 2.5 or less, or 2.4 or less. From the above viewpoint, the degree of dispersion may be 1.0 to 3.0.

The weight average molecular weight and the number average molecular weight in this specification are values measured by gel permeation chromatography (GPC) and converted by using standard polystyrene as a reference sample. As a GPC condition, the following condition can be used.

### {GPC Condition}

Pump: Hitachi L-6000 type (manufactured by Hitachi, Ltd.)
Column: Gelpack GL-R440, Gelpack GL-R450, and Gelpack
GL-R400M (manufactured by Showa Denko Materials Techno Service Co., Ltd., Column Specification: 10.7 mmφ×300 mm) Eluent: tetrahydrofuran
Measurement Temperature: 40° C.
Injection Amount: 200 μL
Flow Rate: 2.05 mL/minute
Detector: L-2490 type RI (manufactured by Hitachi High-Tech Corporation)

The acid value of the component (A), from the viewpoint of easily obtaining the resist pattern including the space portion with a high aspect ratio, may be in the following range. The acid value may be 50 mgKOH/g or more, 80 mgKOH/g or more, 100 mgKOH/g or more, 120 mgKOH/g or more, 150 mgKOH/g or more, 180 mgKOH/g or more, or 190 mgKOH/g or more. The acid value may be 250 mgKOH/g or less, 230 mgKOH/g or less, 220 mgKOH/g or less, 210 mgKOH/g or less, or 200 mgKOH/g or less. From the above viewpoint, the acid value may be 50 to 250 mgKOH/g, 50 to 200 mgKOH/g, or 100 to 200 mgKOH/g.

The acid value can be measured by the following procedure. First, the binder polymer is weighed in a conical flask. Next, a mixed solvent (Mass Ratio: Toluene/Methanol=70/30) is added to dissolve the binder polymer, and then, a phenol phthalein solution is added as an indicator. Then, the acid value is obtained by a titration using 0.1 mol/L (N/10) of a potassium hydroxide solution (an alcohol solution).

The content of the component (A) in the photosensitive resin composition, from the viewpoint of easily obtaining the resist pattern including the space portion with a high aspect ratio, may be in the following range, with respect to 100 parts by mass of the total amount of the component (A) and the component (B). The content of the component (A) may be 10 parts by mass or more, 20 parts by mass or more, 30 parts by mass or more, 35 parts by mass or more, 40 parts by mass or more, 45 parts by mass or more, 50 parts by mass or more, or 55 parts by mass or more. The content of the component (A) may be 90 parts by mass or less, 80 parts by mass or less, 75 parts by mass or less, 70 parts by mass or less, 65 parts by mass or less, or 60 parts by mass or less. From the above viewpoint, the content of the component (A) may be 10 to 90 parts by mass.

### (Component (B): Photopolymerizable Compound)

The photosensitive resin composition contains the photopolymerizable compound as the component (B). As the component (B), a compound having at least one ethylenically unsaturated bond in the molecules can be used.

Examples of the ethylenically unsaturated bond include an α,β-unsaturated carbonyl group (such as a (meth)acryloyl group). Examples of a photopolymerizable compound having an α,β-unsaturated carbonyl group include α,β-unsaturated carboxylic acid ester of polyhydric alcohol, bisphenol-type (meth)acrylate, an α,β-unsaturated carboxylic acid adduct of a glycidyl group-containing compound, (meth)acrylate having a urethane bond, nonyl phenoxypolyethylene oxy(meth)acrylate (also known as nonyl phenoxypolyethylene glycol (meth)acrylate), (meth)acrylate having a phthalic acid skeleton, and alkyl (meth)acrylate ester.

Examples of the α,β-unsaturated carboxylic acid ester of the polyhydric alcohol include polyethylene glycol di(meth)acrylate having 2 to 14 ethylene groups, polypropylene glycol di(meth)acrylate having 2 to 14 propylene groups, polyethylene/polypropylene glycol di(meth)acrylate having 2 to 14 ethylene groups and 2 to 14 propylene groups, trimethylol propane di(meth)acrylate, trimethylol propane tri(meth)acrylate, EO-modified trimethylol propane tri(meth)acrylate, PO-modified trimethylol propane tri(meth)acrylate, EO/PO-modified trimethylol propane tri(meth)acrylate, tetramethylol methane tri(meth)acrylate, tetramethylol methane tetra(meth)acrylate, and a (meth)acrylate compound having a skeleton derived from dipentaerythritol or pentaerythritol. “EO-modified” indicates having a block structure of an ethylene oxide (EO) group, and “PO-modified” indicates having a block structure of a propylene oxide (PO) group.

The component (B), from the viewpoint of easily improving the flexibility of the resist pattern and from the viewpoint of easily obtaining the resist pattern including the space portion with a high aspect ratio, may contain polyalkylene glycol di(meth)acrylate. The polyalkylene glycol di(meth)acrylate may have at least one of an EO group and a PO group, or may have both of an EO group and a PO group. In the polyalkylene glycol di(meth)acrylate having both of an EO group and a PO group, the EO group and the PO group may consecutively exist as a block, or may randomly exist. The PO group may be either an oxy-n-propylene group or an oxyisopropylene group. In the (poly)oxyisopropylene group, the secondary carbon of the propylene group may be bonded to an oxygen atom, or the primary carbon may be bonded to an oxygen atom.

Examples of a commercially available product of the polyalkylene glycol di(meth)acrylate include FA-023M (manufactured by Showa Denko Materials Co., Ltd.), FA-024M (manufactured by Showa Denko Materials Co., Ltd.), and NK ESTETR HEMA-9P (manufactured by SHIN-NAKAMURA CHEMICAL Co., Ltd.).

The component (B), from the viewpoint of easily improving the flexibility of the resist pattern and from the viewpoint of easily obtaining the resist pattern including the space portion with a high aspect ratio, may contain urethane (meth)acrylate, and the urethane (meth)acrylate is (meth)acrylate having a urethane bond. Examples of the (meth)acrylate having a urethane bond include an addition reactant between a (meth)acrylic monomer having a hydroxy group at a β-position and diisocyanate (such as isophorone diisocyanate, 2,6-toluene diisocyanate, 2,4-toluene diisocyanate, and 1,6-hexamethylene diisocyanate), tris((meth)acryloxytetraethylene glycol isocyanate) hexamethylene isocyanurate, EO-modified urethane di(meth)acrylate, PO-modified urethane di(meth)acrylate, and EO/PO-modified urethane di(meth)acrylate.

Examples of a commercially available product of the EO-modified urethane di(meth)acrylate include UA-11 (manufactured by SHIN-NAKAMURA CHEMICAL Co., Ltd.) and UA-21EB (manufactured by SHIN-NAKAMURA CHEMICAL Co., Ltd.).

Examples of a commercially available product of the EO/PO-modified urethane di(meth)acrylate include UA-13 (manufactured by SHIN-NAKAMURA CHEMICAL Co., Ltd.).

The component (B), from the viewpoint of easily obtaining the resist pattern including the space portion with a high aspect ratio and from the viewpoint of easily improving the resolution and the peelability after curing, may contain bisphenol-type (meth)acrylate, or may contain bisphenol A-type (meth)acrylate. Examples of the bisphenol A-type (meth)acrylate include 2-bis(4-((meth)acryloxypolyethoxy)phenyl) propane (for example, 2,2-bis(4-((meth)acryloxypentaethoxy)phenyl) propane), 2,2-bis(4-((meth)acryloxypolypropoxy)phenyl) propane, 2,2-bis(4-((meth)acryloxypolyethoxypolypropoxy)phenyl) propane, 2,2-bis(4-((meth)acryloxypolybutoxy)phenyl) propane, and 2,2-bis(4-((meth)acryloxypentaethoxy)phenyl) propane. The component (B), from the viewpoint of more easily obtaining the resist pattern including the space portion with a high aspect ratio and from the viewpoint of more easily improving the resolution and pattern formability, may contain 2,2-bis(4-((meth)acryloxypolyethoxy)phenyl) propane.

Examples of a commercially available product of the 2,2-bis(4-((meth)acryloxydipropoxy)phenyl) propane include BPE-200 (manufactured by SHIN-NAKAMURA CHEMICAL Co., Ltd.).

Examples of a commercially available product of the 2,2-bis(4-(methacryloxypentaethoxy)phenyl) propane include BPE-500 (manufactured by SHIN-NAKAMURA CHEMICAL Co., Ltd.) and FA-321M (manufactured by Showa Denko Materials Co., Ltd.).

The component (B), from the viewpoint of improving resist peelability and resist dispersibility in a developer, may contain (meth)acrylate having one polymerizable ethylenically unsaturated bond in the molecules. In addition, the (meth)acrylate having one polymerizable ethylenically unsaturated bond in the molecules may be aromatic monofunctional (meth)acrylate. The aromatic monofunctional (meth)acrylate is monofunctional (meth)acrylate having an aromatic hydrocarbon group. Examples of the aromatic monofunctional (meth)acrylate include nonyl phenoxypolyethylene oxy(meth)acrylate and (meth)acrylate having a phthalic acid skeleton.

Examples of the nonyl phenoxypolyethylene oxy(meth)acrylate include nonyl phenoxytetraethylene oxy(meth)acrylate, nonyl phenoxypentaethylene oxy(meth)acrylate, nonyl phenoxyhexaethylene oxy(meth)acrylate, nonyl phenoxyheptaethylene oxy(meth)acrylate, nonyl phenoxyoctaethylene oxy(meth)acrylate, nonyl phenoxynonaethylene oxy(meth)acrylate, nonyl phenoxydecaethylene oxy(meth)acrylate, and nonyl phenoxyundecaethylene oxy(meth)acrylate. Examples of a commercially available product of the nonyl phenoxypolyethylene oxy(meth)acrylate include FA-318A (manufactured by Showa Denko Materials Co., Ltd.).

Examples of the (meth)acrylate having a phthalic acid skeleton include γ-chloro-β-hydroxypropyl-β′-(meth)acryloyl oxyethyl-o-phthalate, β-hydroxyethyl-β′-(meth)acryloyl oxyethyl-o-phthalate, and β-hydroxypropyl-β′-(meth)acryloyl oxyethyl-o-phthalate. Examples of a commercially available product of the γ-chloro-β-hydroxypropyl-β′-methacryloyl oxyethyl-o-phthalate include FA-MECH (manufactured by Showa Denko Materials Co., Ltd.).

The content of the component (B), from the viewpoint of easily obtaining the resist pattern including the space portion with a high aspect ratio, may be in the following range, with respect to 100 parts by mass of the total amount of the component (A) and the component (B). The content of the component (B) may be 10 parts by mass or more, 20 parts by mass or more, 25 parts by mass or more, 30 parts by mass or more, 35 parts by mass or more, or 40 parts by mass or more. The content of the component (B) may be 90 parts by mass or less, 80 parts by mass or less, 70 parts by mass or less, 65 parts by mass or less, 60 parts by mass or less, 55 parts by mass or less, 50 parts by mass or less, or 45 parts by mass or less. From the above viewpoint, the content of the component (B) may be 10 to 90 parts by mass.

In the component (B), the content of the (meth)acrylate having one polymerizable ethylenically unsaturated bond in the molecules described above, from the viewpoint of improving the resist peelability and the resist dispersibility in the developer, may be 1 to 30% by mass, 3 to 20% by mass, or 3 to 15% by mass, on the basis of the total amount of the component (B).

### (Component (C): Photopolymerization Initiator)

The photosensitive resin composition contains the photopolymerization initiator as the component (C). As the component (C), a compound capable of polymerizing the component (B) can be used. The component (C), from the viewpoint of improving the sensitivity and the resolution in a balanced way, may contain at least one type selected from the group consisting of a hexaaryl biimidazole derivative and an acridine compound (a compound having an acridinyl group).

Examples of the hexaaryl biimidazole derivative include 2,2′-bis(2-chlorophenyl)-4,4′,5,5′-tetraphenyl biimidazole, 2-(o-chlorophenyl)-4,5-diphenyl biimidazole, 2,2′,5-tris-(o-chlorophenyl)-4-(3,4-dimethoxyphenyl)-4′,5′-diphenyl biimidazole, 2,4-bis-(o-chlorophenyl)-5-(3,4-dimethoxyphenyl)-diphenyl biimidazole, 2,4,5-tris-(o-chlorophenyl)-diphenyl biimidazole, 2-(o-chlorophenyl)-bis-4,5-(3,4-dimethoxyphenyl)-biimidazole, 2,2′-bis-(2-fluorophenyl)-4,4′,5,5′-tetrakis-(3-methoxyphenyl)-biimidazole, 2,2′-bis-(2,3-difluoromethyl phenyl)-4,4′,5,5′-tetrakis-(3-methoxyphenyl)-biimidazole, 2,2′-bis-(2,4-difluorophenyl)-4,4′,5,5′-tetrakis-(3-methoxyphenyl)-biimidazole, and 2,2′-bis-(2,5-difluorophenyl)-4,4′,5,5′-tetrakis-(3-methoxyphenyl)-biimidazole.

Examples of the acridine compound include 9-phenyl acridine, 9-(p-methyl phenyl) acridine, 9-(m-methyl phenyl) acridine, 9-(p-chlorophenyl) acridine, 9-(m-chlorophenyl) acridine, 9-aminoacridine, 9-dimethyl aminoacridine, 9-diethyl aminoacridine, 9-pentyl aminoacridine, bis(9-acridinyl) alkane (such as 1,2-bis(9-acridinyl) ethane, 1,4-bis(9-acridinyl) butane, 1,6-bis(9-acridinyl) hexane, 1,8-bis(9-acridinyl) octane, 1,10-bis(9-acridinyl) decane, 1,12-bis(9-acridinyl) dodecane, 1,14-bis(9-acridinyl) tetradecane, 1,16-bis(9-acridinyl) hexadecane, 1,18-bis(9-acridinyl) octadecane, and 1,20-bis(9-acridinyl) eicosane), 1,3-bis(9-acridinyl)-2-oxapropane, and 1,3-bis(9-acridinyl)-2-thiapropane, 1,5-bis(9-acridinyl)-3-thiapentane.

The content of the component (C) may be in the following range, with respect to 100 parts by mass of the total amount of the component (A) and the component (B). The content of the component (C), from the viewpoint of easily improving the photosensitivity, the resolution, and the adhesiveness, may be 0.1 parts by mass or more, 1 part by mass or more, 2 parts by mass or more, or 3 parts by mass or more. The content of the component (C), from the viewpoint of easily obtaining excellent pattern formability, may be 10 parts by mass or less, 5 parts by mass or less, 4 parts by mass or less, or 3 parts by mass or less. From the above viewpoint, the content of the component (C) may be 0.1 to 10 parts by mass.

### (Component (D): Coumarin-Based Sensitizer)

The photosensitive resin composition contains the coumarin-based sensitizer as the component (D). By using the component (D), it is possible to form the photosensitive layer that has a high sensitivity to the active ray and is capable of obtaining the resist pattern including the space portion with a high aspect ratio. Since a high sensitivity is obtained, whereas an absorbance is low even in a case where the added amount of the coumarin-based sensitizer is small, it is easy for exposure light to reach the deep portion of the photosensitive layer when forming the resist pattern, and it is possible to increase the photocuring property of the bottom portion of the photosensitive layer. Therefore, it is possible to form the resist pattern including the space portion with a high aspect ratio. In addition, by using the component (D), it is possible to form the resist pattern that has reduced residue (tailing) in the bottom portion of the resist and has an excellent resist shape with approximately perpendicular lateral surfaces (for example, a rectangular cross section).

Examples of the component (D) include a compound represented by General Formula (1) described below.

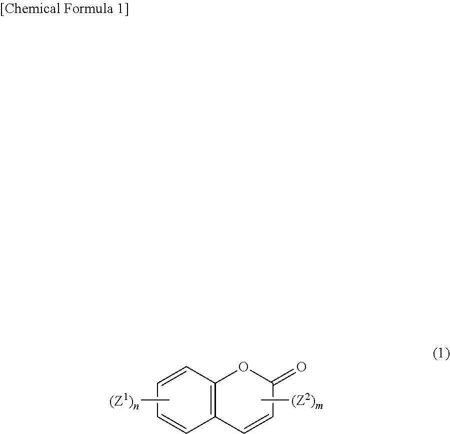

In the formula, Z¹ and Z² each independently indicate a halogen atom, an alkyl group having 1 to 20 carbon atoms, a cycloalkyl group having 3 to 10 carbon atoms, an aryl group having 6 to 14 carbon atoms, an amino group, an alkyl amino group having 1 to 10 carbon atoms, a dialkyl amino group having 2 to 20 carbon atoms, a mercapto group, an alkyl mercapto group having 1 to 10 carbon atoms, an allyl group, a hydroxyalkyl group having 1 to 20 carbon atoms, a carboxyl group, a carboxyalkyl group in which the number of carbon atoms of an alkyl group is 1 to 10, an acyl group in which the number of carbon atoms of an alkyl group is 1 to 10, an alkoxyl group having 1 to 20 carbon atoms, an alkoxycarbonyl group having 1 to 20 carbon atoms, or a group having a heterocyclic ring, n indicates an integer of 0 to 4, and m indicates an integer of 0 to 2. Note that at least two of n Z¹'s and m Z²'s may form a ring.

In General Formula (1), it is preferable that at least one Z¹ is substituted at a 7-position, and it is preferable that at least one Z² is substituted at a 4-position. In addition, from the viewpoint of the sensitivity, it is preferable that there is no substitution at a 3-position.

Examples of the halogen atom in General Formula (1) include fluorine, chlorine, bromine, iodine, and astatine, and examples of the alkyl group having 1 to 20 carbon atoms include a methyl group, an ethyl group, a n-propyl group, an isopropyl group, a n-butyl group, an isobutyl group, a sec-butyl group, a tert-butyl group, a pentyl group, an isopentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an icosyl group, and structural isomers thereof. In addition, examples of the cycloalkyl group having 3 to 10 carbon atoms include a cyclopropyl group, a cyclobutyl group, a cyclopentyl group, a cyclohexyl group, a cycloheptyl group, and a cyclooctyl group. Examples of the aryl group having 6 to 14 carbon atoms include a phenyl group, a tolyl group, a xylyl group, a biphenyl group, a naphthyl group, an anthryl group, and a phenanthryl group, which may be substituted with a halogen atom, an amino group, a nitro group, a cyano group, a mercapto group, an allyl group, an alkyl group having 1 to 20 carbon atoms, and the like. Examples of the alkyl amino group having 1 to 10 carbon atoms include a methyl amino group, an ethyl amino group, a propyl amino group, an isopropyl amino group, and the like, and examples of the dialkyl amino group having 2 to 20 carbon atoms include a dimethyl amino group, a diethyl amino group, a dipropyl amino group, and a diisopropyl amino group. Then, examples of the alkyl mercapto group having 1 to 10 carbon atoms include a methyl mercapto group, an ethyl mercapto group, and a propyl mercapto group. Further, examples of the hydroxyalkyl group having 1 to 20 carbon atoms include a hydroxymethyl group, a hydroxyethyl group, a hydroxypropyl group, a hydroxyisopropyl group, and a hydroxybutyl group, and examples of the carboxyalkyl group in which the number of carbon atoms of the alkyl group is 1 to 10 include a carboxymethyl group, a carboxyethyl group, a carboxypropyl group, and a carboxybutyl group. In addition, examples of the acyl group in which the number of carbon atoms of the alkyl group is 1 to 10 include a formyl group, an acetyl group, a propionyl group, a butyryl group, an isobutyryl group, a valeryl group, an isovaleryl group, and a pivaloyl group, and examples of the alkoxy group having 1 to 20 carbon atoms include a methoxy group, an ethoxy group, a propoxy group, and a butoxy group. Then, examples of the alkoxycarbonyl group having 1 to 20 carbon atoms include a methoxycarbonyl group, an ethoxycarbonyl group, a propoxycarbonyl group, and a butoxycarbonyl group, and examples of the group having a heterocyclic ring include a furyl group, a thienyl group, a pyrrolyl group, a thiazolyl group, an indolyl group, and a quinolyl group.

In General Formula (1), it is preferable that Z¹ and Z² each independently indicate an alkyl group having 1 to 20 carbon atoms, an amino group, an alkyl amino group having 1 to 10 carbon atoms, or a dialkyl amino group having 2 to 20 carbon atoms. Even in such a case, at least two of n Z¹'s and m Z²'s may form a ring.

From the viewpoint of the resolution and the photosensitivity, it is preferable that the coumarin compound represented by General Formula (1) is a compound represented by General Formula (2) described below. Note that in General Formula (2), Z¹, Z², and m are the same as Z¹, Z², and m described above, and Z¹¹ and Z¹² each independently indicate a hydrogen atom or an alkyl group having 1 to 20 carbon atoms, and r indicates an integer of 0 to 3. Note that at least two of r Z¹'s, m Z²'s, and Z¹¹ and Z¹² may form a ring. Then, in the compound represented by General Formula (2) described below, Z¹¹ and Z¹² each independently indicate preferably an alkyl group having 1 to 10 carbon atoms, and more preferably an alkyl group having 1 to 6 carbon atoms. In addition, preferred Z¹ and Z² are the same as described above.

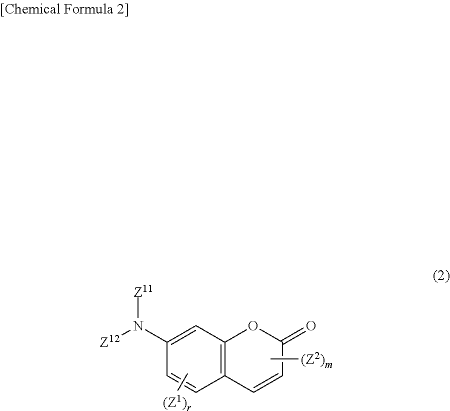

Examples of the compound represented by General Formula (2) in which at least two of m Z²'s, and Z¹¹ and Z¹² form a ring include a compound represented by General Formula (3) described below and a compound represented by General Formula (4) described below.

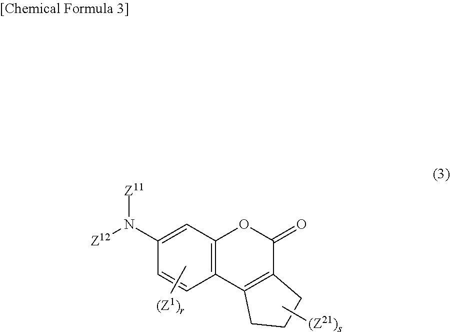

In the formula, Z¹, Z¹¹, Z¹², and r are the same as Z¹, Z¹¹, Z¹², and r described above, and Z²¹ indicates the same atoms or groups as Z¹. In addition, s indicates an integer of 0 to 8. Note that preferred Z¹, Z¹¹, and Z¹² are the same as described above.

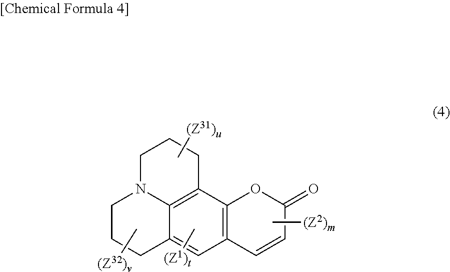

In the formula, Z¹, Z², and m are the same as Z¹, Z², and m described above, and Z³¹ and Z³² each independently indicate the same atoms or groups as Z¹ described above. In addition, t indicates an integer of 0 to 1, u indicates an integer of 0 to 6, and v indicates an integer of 0 to 6. Note that preferred Z¹ and Z² are the same as described above.

Examples of the compound represented by General Formula (2) (including the compounds represented by General Formulae (3) and (4)) include 7-amino-4-methyl coumarin, 7-dimethyl amino-4-methyl coumarin, and 7-diethyl amino-4-methyl coumarin (a compound represented by Formula (5) described below), 7-methyl amino-4-methyl coumarin, 7-ethyl amino-4-methyl coumarin, and 4,6-dimethyl-7-ethyl aminocoumarin (a compound represented by Formula (6) described below), 4,6-diethyl-7-ethyl aminocoumarin, 4,6-dimethyl-7-diethyl aminocoumarin, 4,6-dimethyl-7-dimethyl aminocoumarin, 4,6-diethyl-7-diethyl aminocoumarin, 4,6-diethyl-7-dimethyl aminocoumarin, 4,6-dimethyl-7-ethyl aminocoumarin, and 7-dimethyl aminocyclopenta[c]coumarin (a compound represented by Formula (7) described below), 7-aminocyclopenta[c]coumarin, 7-diethyl aminocyclopenta[c]coumarin, 2,3,6,7,10,11-hexaanhydro-1H,5H-cyclopenta[3,4][1]benzopyrano[6,7,8-ij]quinolizin 12(9H)-one, 7-diethyl amino-5′,7′-dimethoxy-3,3′-carbonyl biscoumarin, 3,3′-carbonyl bis[7-(diethyl amino)coumarin], 7-(diethyl amino)-3-(2-thienyl) coumarin, and a compound represented by Formula (8) described below.

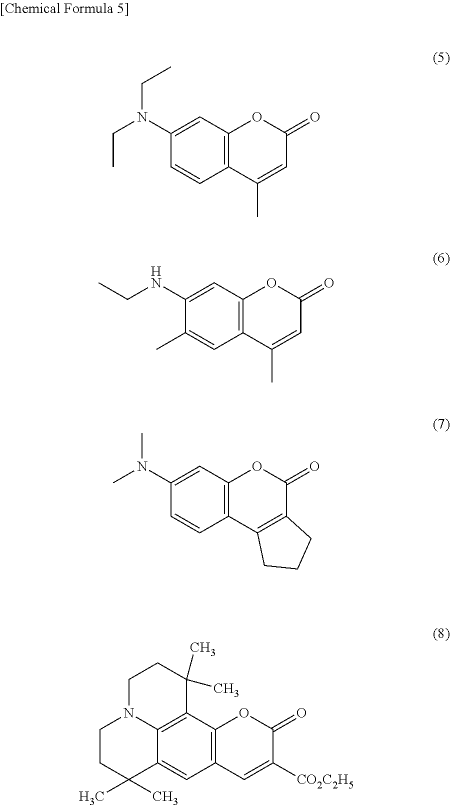 [SMILES: CCN(CC)c1ccc2c(C)cc(=O)oc2c1 ; CCNc1cc2oc(=O)cc(C)c2cc1C ; CN(C)c1ccc2c3c(c(=O)oc2c1)CCC3 ; CCOC(=O)c1cc2cc3c4c(c2oc1=O)C(C)(C)CCN4CCC3(C)C]

As the coumarin compound represented by General Formula (1), the compound represented by General Formula (4) is particularly preferable. By using the compound represented by General Formula (4) as the component (D), it is possible to significantly improve the sensitivity, the adhesiveness, and the resolution, form the resist pattern including the space portion with a higher aspect ratio, and sufficiently obtain such an effect by adding only a small amount of component (D).

The content of the component (D), from the viewpoint of further improving the sensitivity, the adhesiveness, and the resolution, for example, is 0.01 parts by mass or more, preferably 0.02 parts by mass or more, more preferably 0.03 parts by mass or more, and even more preferably 0.04 parts by mass or more, and from the viewpoint of making the shape of the resist pattern more excellent and obtaining the resist pattern including the space portion with a higher aspect ratio, for example, is 0.5 parts by mass or less, preferably 0.4 parts by mass or less, more preferably 0.3 parts by mass or less, even more preferably 0.2 parts by mass or less, particularly preferably 0.15 parts by mass or less, and extremely preferably 0.1 parts by mass or less, with respect to 100 parts by mass of the total amount of the component (A) and the component (B). In addition, the content of the component (D), from the viewpoint of making the shape of the resist pattern more excellent and obtaining the resist pattern including the space portion with a higher aspect ratio, may be less than 0.1 parts by mass, 0.09 parts by mass or less, or less than 0.05 parts by mass, with respect to 100 parts by mass of the total amount of the component (A) and the component (B).

The photosensitive resin composition may further contain a known photosensitizer, as other photosensitizers in addition to the component (D). The content of the other sensitizers, for example, may be 0.01 to 0.50 parts by mass, or 0.05 to 0.20 parts by mass, with respect to 100 parts by mass of the total amount of the component (A) and the component (B).

### (Other Components)

The photosensitive resin composition, from the viewpoint of suppressing polymerization in an unexposed portion when forming the resist pattern and further improving the resolution, may contain a polymerization inhibitor. By using the polymerization inhibitor, it is possible to improve the pattern formability.

The polymerization inhibitor, from the viewpoint of easily improving the pattern formability, may contain a compound represented by General Formula (I) described below.

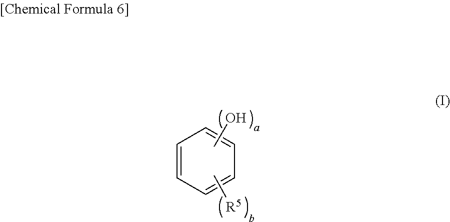

In Formula (I), R⁵ indicates a halogen atom, a hydrogen atom, an alkyl group having 1 to 20 carbon atoms, a cycloalkyl group having 3 to 10 carbon atoms, an amino group, an aryl group, a mercapto group, an alkyl mercapto group having 1 to 10 carbon atoms, a carboxyl alkyl group in which the number of carbon atoms of an alkyl group is 1 to 10, an alkoxy group having 1 to 20 carbon atoms, or a heterocyclic group, a is an integer of 2 or more, b is an integer of 0 or more, a+b=6 is satisfied, and in a case where b is an integer of 2 or more, R⁵'s may be identical to each other, or may be different from each other. The aryl group may be substituted with an alkyl group having 1 to 20 carbon atoms.

R⁵, from the viewpoint of easily improving compatibility with the component (A), may be a hydrogen atom, or an alkyl group having 1 to 20 carbon atoms. The alkyl group having 1 to 20 carbon atoms, represented by R⁵, may be an alkyl group having 1 to 4 carbon atoms. a, from the viewpoint of easily improving the resolution, may be 2 or 3, or may be 2.

Examples of the compound represented by General Formula (I) include a catechol compound (a compound having two hydroxy groups at an ortho-position on a benzene ring) such as catechol, 2-methyl catechol, 3-methyl catechol, 4-methyl catechol, 2-ethyl catechol, 3-ethyl catechol, 4-ethyl catechol, 2-propyl catechol, 3-propyl catechol, 4-propyl catechol, 2-n-butyl catechol, 3-n-butyl catechol, 4-n-butyl catechol, 2-tert-butyl catechol, 3-tert-butyl catechol, 4-tert-butyl catechol, and 3,5-di-tert-butyl catechol; a resorcinol compound such as resorcinol (resorcin), 2-methyl resorcinol, 4-methyl resorcinol, 5-methyl resorcinol (orcin), 2-ethyl resorcinol, 4-ethyl resorcinol, 2-propyl resorcinol, 4-propyl resorcinol, 2-n-butyl resorcinol, 4-n-butyl resorcinol, 2-tert-butyl resorcinol, and 4-tert-butyl resorcinol; a hydroquinone compound such as 1,4-hydroquinone, methyl hydroquinone, ethyl hydroquinone, propyl hydroquinone, tert-butyl hydroquinone, and 2,5-di-tert-butyl hydroquinone; an alkoxyquinone compound such as methoquinone; and a trivalent phenol compound such as pyrogallol and phloroglucinol.

The polymerization inhibitor, from the viewpoint of easily improving the resolution and from the viewpoint of easily obtaining the resist pattern including the space portion with a high aspect ratio, may contain a catechol compound, may contain alkyl catechol, may contain at least one type selected from the group consisting of 2-methyl catechol, 3-methyl catechol, 4-methyl catechol, 2-ethyl catechol, 3-ethyl catechol, 4-ethyl catechol, 2-propyl catechol, 3-propyl catechol, 4-propyl catechol, 2-n-butyl catechol, 3-n-butyl catechol, 4-n-butyl catechol, 2-tert-butyl catechol, 3-tert-butyl catechol, 4-tert-butyl catechol, and 3,5-di-tert-butyl catechol, or may contain at least one type selected from the group consisting of 3-tert-butyl catechol, 4-tert-butyl catechol, and 3,5-di-tert-butyl catechol.

The content of the polymerization inhibitor may be in the following range, with respect to 100 parts by mass of the total amount of the component (A) and the component (B). The content of the polymerization inhibitor may be 0 parts by mass or greater than 0 parts by mass, and from the viewpoint of easily increasing the pattern formability by causing a photoreaction in a photocured portion to sufficiently proceed, may be 0.001 parts by mass or more, 0.005 parts by mass or more, 0.01 parts by mass or more, or 0.015 parts by mass or more. The content of the polymerization inhibitor, from the viewpoint of easily shortening an exposure time, may be 1 part by mass or less, less than 1 part by mass, 0.8 parts by mass or less, 0.5 parts by mass or less, 0.3 parts by mass or less, 0.2 parts by mass or less, 0.15 parts by mass or less, 0.1 parts by mass or less, 0.08 parts by mass or less, 0.05 parts by mass or less, 0.03 parts by mass or less, or 0.02 parts by mass or less. From the above viewpoint, the content of the polymerization inhibitor may be 0 to 1 parts by mass, greater than 0 parts by mass and less than 1 part by mass, or 0.01 to 0.3 parts by mass. In a case where the polymerization inhibitor contains the catechol compound, the content of the polymerization inhibitor may be greater than 0 parts by mass and less than 1 part by mass.

In addition, the polymerization inhibitor, from the viewpoint of improving the curability of the bottom portion and improving the resist shape, may contain 3,5-di-tert-butyl-4-hydroxytoluene and methoquinone. In this case, the content of the 3,5-di-tert-butyl-4-hydroxytoluene is 20 to 200 ppm by mass, and the content of the methoquinone is 10 to 100 ppm by mass, on the basis of the total solid content of the photosensitive resin composition.

The photosensitive resin composition may contain Leuco crystal violet. Accordingly, it is easy to improve the photosensitivity and the resolution of the photosensitive layer in a balanced way. It is considered that the Leuco crystal violet has a property as a color former (a photocolor former) that absorbs light to produce a specific color, and attains the effect described above due to the property described above. The content of the Leuco crystal violet may be 0.01 to 10 parts by mass, 0.05 to 5 parts by mass, or 0.1 to 3 parts by mass, with respect to 100 parts by mass of the total amount of the component (A) and the component (B).

The photosensitive resin composition may contain other components. Examples of the other components include a dye (such as malachite green), tribromophenyl sulfone, a color former (excluding the Leuco crystal violet), a thermal color formation inhibitor, a plasticizer (such as p-toluene sulfone amide), a pigment, a filling agent, an antifoaming agent, a flame retarder, a stabilizer, an adhesiveness imparting agent, a leveling agent, a peeling accelerator, an antioxidant, a fragrance, an imaging agent, and a thermal cross-linking agent.

The photosensitive layer, for example, can be formed by applying the photosensitive resin composition onto the support, and then, drying the photosensitive resin composition. The coating of the photosensitive resin composition, for example, can be performed by using a known method such as roll coating, comma coating, gravure coating, air knife coating, die coating, and bar coating. The drying, for example, can be performed at 70 to 150° C. for approximately 5 to 30 minutes.

When applying the photosensitive resin composition onto the support, as necessary, a solvent may be added to use the photosensitive resin composition with a solid content of approximately 30 to 60% by mass. Examples of the solvent include methanol, ethanol, acetone, methyl ethyl ketone, methyl cellosolve, ethyl cellosolve, toluene, N,N-dimethyl formamide, and propylene glycol monomethyl ether.

In the photosensitive element according to this embodiment, the thickness of the photosensitive layer is 30 μm or more. The thickness of the photosensitive layer, from the viewpoint of easily obtaining the resist pattern including the space portion with a high aspect ratio, may be 35 μm or more, 40 μm or more, 45 μm or more, 50 μm or more, 55 μm or more, 60 μm or more, 75 μm or more, 100 μm or more, or greater than 100 μm. The thickness of the photosensitive layer, from the viewpoint of being excellent in the peelability of the photosensitive layer, may be 300 μm or less, 250 μm or less, 200 μm or less, 150 μm or less, or 120 μm or less. The thickness of the photosensitive layer may be the average thickness of the thicknesses at 10 spots. The photosensitive layer may have the thickness described above by stacking a plurality of photosensitive layers.

The photosensitive element according to this embodiment may further include a protective film on the surface of the photosensitive layer on a side opposite to the support. As the protective film, a polymer film such as a polyethylene film and a polypropylene film may be used. As the protective film, a polymer film identical to the support may be used, or a polymer film different from the support may be used. A bonding adhesive force between the protective film and the photosensitive layer may be lower than a bonding adhesive force between the support and the photosensitive layer.

The shape of the photosensitive element is not particularly limited, and may be in the shape of a sheet, or may be in the shape of a roll in which the photosensitive element is wound around a core. In a case where the photosensitive element is wound into the shape of a roll, the support is on the outside.

### <Method for Forming Resist Pattern and Method for Producing Stacked Body>

A method for forming a resist pattern according to this embodiment includes a step of providing a photosensitive layer on a base material by using the photosensitive element according to this embodiment (a photosensitive layer forming step), a step of irradiating at least a part of the photosensitive layer with an active ray to form a photocured portion (an exposing step), and a step of removing at least a part of the photosensitive layer other than the photocured portion to form a resist pattern (a developing step).

In the photosensitive layer forming step, the photosensitive layer is formed on the base material by using the photosensitive element according to this embodiment. In the photosensitive layer forming step, the photosensitive layer of the photosensitive element according to this embodiment may be stacked on the base material to form the photosensitive layer on the base material. In a case where the photosensitive element includes the protective film, the photosensitive layer can be stacked on the base material after the protective film is removed. In the photosensitive layer forming step, for example, by stacking the photosensitive layer on the base material by crimping at a pressure of approximately 0.1 to 1 MPa (approximately 1 to 10 kgf/cm²) under a reduced pressure or under an ordinary pressure while heating the photosensitive layer of the photosensitive element to approximately 70 to 130° C., it is possible to form the photosensitive layer on the base material.

As the base material, a stacked body including an insulating layer, and a metal layer disposed on the insulating layer may be used, and for example, a copper clad laminate in which a copper foil is provided on one surface or both surfaces of a layer consisting of an insulating material such as a glass-fiber reinforced epoxy resin can be used.

In the exposing step, by irradiating at least a part of the photosensitive layer with the active ray, it is possible to form the photocured portion. In the exposing step, at least a part of the photosensitive layer may be irradiated with the active ray after the support is removed, or at least a part of the photosensitive layer may be irradiated with the active ray through the support. As an exposure method, a method for applying an active ray into the shape of an image through a negative or positive mask pattern referred to as artwork (a mask exposure method), a method for applying an active ray into the shape of an image by a projection exposure method, a method for applying an active ray into the shape of an image by a direct lithographic exposure method such as a laser direct imaging (LDI) exposure method and a digital light processing (DLP) exposure method, and the like.

As a light source of the active ray, a light source for effectively emitting an ultraviolet ray or visible light may be used, and examples thereof include a carbon arc lamp, a mercury-vapor arc lamp, a high-pressure mercury lamp, a xenon lamp, gas laser (such as argon laser), solid-state laser (such as YAG laser), semiconductor laser, and the like.

In the method for forming a resist pattern according to this embodiment, from the viewpoint of improving the adhesiveness, post exposure bake (PEB) may be performed after the exposing step and before the developing step. A temperature in the case of performing PEB may be 50 to 100° C. As a heater, a hot plate, a box-type dryer, a heat roll, and the like may be used.

In the developing step, at least a part of the photosensitive layer other than the photocured portion is removed from the base material as the unexposed portion of the photosensitive layer to form the resist pattern on the base material. In the developing step, a part or all of the unexposed portion of the photosensitive layer is removed. In the case of using the stacked body including the metal layer disposed on the insulating layer as the base material, by removing the unexposed portion of the photosensitive layer, it is possible to expose the metal layer.

In a case where there is the support on the photosensitive layer, the portion (the unexposed portion) of the photosensitive layer other than the photocured portion can be removed (developed), after the support is removed. As a development method, wet development or dry development can be used.

In the case of the wet development, development can be performed using a developer according to the composition of the photosensitive layer by a known development method. Examples of the development method include a dipping method, a puddle method, a spray method, a method using brushing, slapping, scrubbing, or fluctuating immersion, and the like, and from the viewpoint of easily improving the resolution, a high-pressure spray method may be used. The development may be performed by combining two or more types of development methods.

The configuration of the developer is suitably selected in accordance with the composition of the photosensitive layer. Examples of the developer include an alkaline aqueous solution and an organic solvent developer.

As the developer, from the viewpoint of safety and stability, and excellent manipulativeness, the alkaline aqueous solution may be used. As the base of the alkaline aqueous solution, alkali hydroxide (a hydroxide of lithium, sodium, or potassium, and the like), alkali carbonate (a carbonate or a bicarbonate of lithium, sodium, potassium, or ammonium, and the like), an alkali metallic phosphate (potassium phosphate, sodium phosphate, and the like), an alkali metallic pyrophosphate (sodium pyrophosphate, potassium pyrophosphate, and the like), borax, sodium metasilicate, tetramethyl ammonium hydroxide, ethanol amine, ethylene diamine, diethylene triamine, 2-amino-2-hydroxymethyl-1,3-propanediol, 1,3-diamino-2-propanol, morpholine, and the like.

Examples of the alkaline aqueous solution include 0.1 to 5% by mass of a sodium carbonate aqueous solution, 0.1 to 5% by mass of a potassium carbonate aqueous solution, and 0.1 to 5% by mass of a hydroxide sodium aqueous solution. The pH of the alkaline aqueous solution may be 9 to 11. The temperature of the alkaline aqueous solution can be adjusted in accordance with the developing property of the photosensitive layer.

The alkaline aqueous solution, for example, may contain a surfactant, an antifoaming agent, a small amount of organic solvent for accelerating development, and the like. Examples of the organic solvent used for the alkaline aqueous solution include acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether. Examples of an organic solvent used for the organic solvent developer include 1,1,1-trichloroethane, N-methyl pyrrolidone, N,N-dimethyl formamide, cyclohexanone, methyl isobutyl ketone, and γ-butyrolactone. By mixing the organic solvent with water, the content of the organic solvent in the organic solvent developer may be adjusted to a range of 1 to 20% by mass.

The method for forming a resist pattern according to this embodiment, as necessary, may include a step of further curing the resist pattern by heating at approximately 60 to 250° C. or exposing at approximately 0.2 to 10 J/cm², after the developing step.

The resist pattern formed by the method for forming a resist pattern according to this embodiment may be the resist pattern including the space portion with the aspect ratio of 1.3 or more. The aspect ratio of the space portion may be 1.3 to 5.0. Here, in a case where the space portion is a linear pattern, the aspect ratio of the space portion indicates a value obtained by dividing the height of the space portion (the thickness of the resist pattern) by the width of the space portion, and in a case where he space portion is in the shape of a cylinder, the aspect ratio of the space portion indicates a value obtained by dividing the height of the space portion (the thickness of the resist pattern) by the diameter of the space portion. According to the photosensitive element of this embodiment, it is possible to form the resist pattern including the space portion with a high aspect ratio as described above.

A method for producing a stacked body according to this embodiment includes a conductor layer forming step of forming a resist pattern by the method for forming a resist pattern, and then, forming a conductor layer (for example, a metal layer) in at least a part of a portion of a base material in which the resist pattern is not formed.

In the conductor layer forming step, a conductor pattern (for example, a wiring pattern) may be obtained as the conductor layer, and the method for producing a stacked body according to this embodiment may be a method for producing (a method for forming) a conductor pattern (for example, a wiring pattern). Examples of the configuration material of the conductor layer include copper, solder, nickel, and gold. The aspect ratio of the conductor layer may be 1.3 or more, or may be 1.3 to 5.0. In a case where the conductor layer is a linear pattern, the aspect ratio of the conductor layer indicates a value obtained by dividing the thickness of the conductor layer by the width of the conductor layer, and in a case where the conductor layer is in the shape of a cylinder, the aspect ratio of the conductor layer indicates a value obtained by dividing the thickness of the conductor layer by the diameter of the conductor layer.

The conductor pattern may be a conductive coil of an inductor (such as a power inductor), or may be a copper pillar configuring a connecting portion of a semiconductor device. The method for producing a stacked body according to this embodiment may be a method for producing an inductor, a wiring board (for example, a printed wiring board), a semiconductor device, or the like, which includes such a conductor pattern.

In the conductor layer forming step, at least a part of the portion of the base material in which the resist pattern is not formed may be subjected to a plating treatment to form the conductor layer. In the conductor layer forming step, at least a part of the portion of the base material in which the resist pattern is not formed may be subjected to the plating treatment by using the resist pattern as a mask. In the case of using the stacked body including the metal layer disposed on the insulating layer as the base material, the metal layer exposed to the portion of the base material in which the resist pattern is not formed may be subjected to the plating treatment.

The plating treatment may be an electrolytic plating treatment, or may be an electroless plating treatment. Examples of the electroless plating treatment include copper plating such as copper sulfate plating and copper pyrophosphate plating; solder plating such as high throw solder plating; nickel plating such as Watts bath (nickel sulfate-nickel chloride) plating and nickel sulfamate plating; and gold plating such as hard gold plating and soft gold plating.

The method for producing a stacked body according to this embodiment may include a cured product removing step of removing at least a part of the resist pattern, after the conductor layer forming step. In the cured product removing step, a part or all of the resist pattern may be removed.

The resist pattern, for example, can be removed by peeling with an alkaline aqueous solution stronger than the alkaline aqueous solution used in the developing step. As such a strong alkaline aqueous solution, for example, 1 to 10% by mass of a hydroxide sodium aqueous solution, 1 to 10% by mass of a potassium hydroxide aqueous solution, and the like can be used. Examples of a method for removing a resist pattern include an immersion method and a spray method. Such methods for removing a resist pattern may be used alone, or may be used together.

In the case of using the stacked body including the metal layer disposed on the insulating layer as the base material, in the cured product removing step, a portion of the metal layer that is covered with the resist pattern is exposed. The method for producing a stacked body according to this embodiment may include a step of removing the exposed portion of the metal layer, after the cured product removing step. The metal layer, for example, can be removed by an etching treatment.

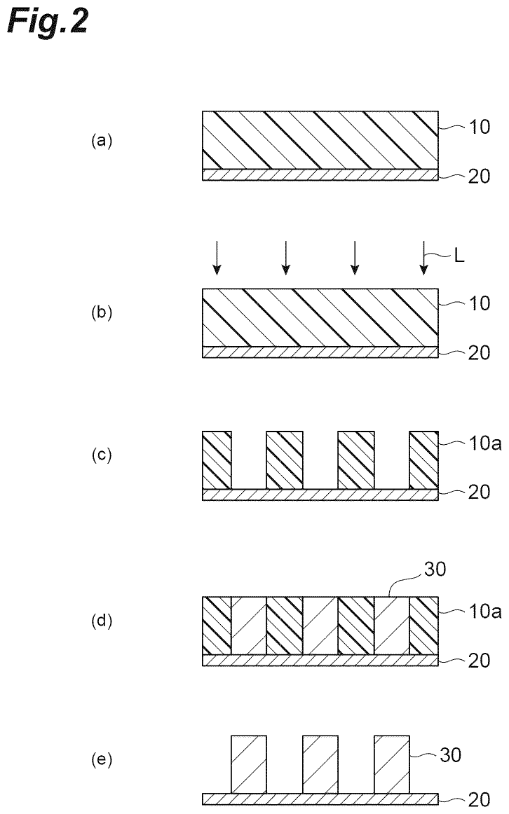

FIG. 2 is a schematic cross-sectional view illustrating an example of the method for producing a stacked body.

First, as illustrated in (a) in FIG. 2, in the photosensitive layer forming step, the photosensitive layer 10 is formed on the base material 20 by using the photosensitive element 1 in FIG. 1. In the photosensitive layer forming step, for example, as the photosensitive layer 10, the photosensitive layer 1a of the photosensitive element 1 is stacked on the base material 20, and then, the support 1b is peeled. As the base material 20, the stacked body including the metal layer disposed on the insulating layer can be used.

Next, as illustrated in (b) in FIG. 2, in the exposing step, the photosensitive layer 10 is irradiated with an active ray L to form the photocured portion.

Next, as illustrated in (c) in FIG. 2, in the developing step, the uncured portion of the photosensitive layer 10 is removed to form a resist pattern (a cured product pattern) 10a.

Next, as illustrated in (d) in FIG. 2, in the conductor layer forming step, the plating treatment is performed by using the resist pattern 10a as a mask to form a conductor layer (a plating layer) 30 in the portion of the base material 20 in which the resist pattern 10a is not formed.

Next, as illustrated in (e) in FIG. 2, in the cured product removing step, the resist pattern 10a is removed. Accordingly, it is possible to obtain the stacked body including the conductor layer 30 as the conductor pattern.

### EXAMPLES

Hereinafter, the present disclosure will be described in more detail by Examples, but the present disclosure is not limited to such Examples.

### Examples 1 to 3 and Comparative Examples 1 and 2

### <Production of Photosensitive Resin Composition>

Each material shown in Table 1 was mixed in a blending amount (Unit: parts by mass) shown in the same table to produce a solution of a photosensitive resin composition. Note that the blending amount (parts by mass) of a component other than a solvent shown in Table 1 is the mass of a non-volatile content (a solid content). The details of each component shown in Table 1 are as follows.

### (Binder Polymer (A))

A-1: an ethylene glycol monomethyl ether/toluene solution (Solid Content: 45% by mass) of a copolymer of Methacrylic Acid/Methyl Methacrylate/Styrene/Benzyl Methacrylate (Mass Ratio: 27/5/45/23, Mw: 47000, Acid Value: 176.1 mgKOH/g, Tg: 107° C.)

A-2: an ethylene glycol monomethyl ether/toluene solution (Solid Content: 45% by mass) of a copolymer of Methacrylic Acid/Methyl Methacrylate/Ethyl Acrylate/Styrene/Butyl Methacrylate (Mass Ratio: 30/22/10/8/30, Mw: 50000, Acid Value: 196 mgKOH/g, Tg: 95.6° C.)

### (Photopolymerizable Compound (B))

FA-321M: 2,2-bis(4-(methacryloxypentaethoxy)phenyl) propane (manufactured by Showa Denko Materials Co., Ltd., Number of EO Groups: 10 (the average value))

UA-11: polyoxyethylene urethane dimethacrylate (manufactured by SHIN-NAKAMURA CHEMICAL Co., Ltd.)

UA-13: polyoxyethylene polyoxypropylene urethane dimethacrylate (manufactured by SHIN-NAKAMURA CHEMICAL Co., Ltd.)

FA-023M: polyalkylene glycol dimethacrylate (manufactured by Showa Denko Materials Co., Ltd., Number of EO Groups: 6 (the average value), Number of PO Groups: 12 (the average value))

FA-318A: nonyl phenoxypolyethylene glycol acrylate (manufactured by Showa Denko Materials Co., Ltd.) (Photopolymerization Initiator (C))

B-CIM: 2,2′-bis(2-chlorophenyl)-4,4′,5,5′-tetraphenyl biimidazole (manufactured by Changzhou Tronly New Electronic Materials Co., Ltd.)

### (Coumarin-Based Sensitizer (D))

Coumarin 102: 2,3,6,7-tetrahydro-9-methyl-1H,5H,11H-[1]benzopyrano[6,7,8-ij]quinolizin-11-one (manufactured by Tokyo Chemical Industry Co., Ltd.)

### (Other Components)

EAB: 4,4′-bis(diethyl amino)benzophenone (manufactured by Hodogaya Chemical Co., Ltd.) (a sensitizer)

LCV: Leuco crystal violet (manufactured by Yamada Chemical Co., Ltd.) (a color former)

Q-TBC-5P: 4-tert-butyl catechol (manufactured by DIC Corporation) (a polymerization inhibitor)

MKG: malachite green (manufactured by OSAKA ORGANIC CHEMICAL INDUSTRY LTD.) (a dye)

SH-193: a leveling agent (manufactured by Toray Dow Corning Silicone Co., Ltd.)

### (Solvent)

MAL: methanol

TLS: toluene

ACS: acetone

### <Production of Photosensitive Element>

The solution of the photosensitive resin composition was evenly applied onto a PET film (a support, Thickness: 16 μm, manufactured by Toray Industries, Inc., Product Name: FB-40), and then, dried with a hot-air convection dryer at 70° C. for 10 minutes and at 100° C. for 10 minutes to produce a photosensitive element including a photosensitive layer consisting of the photosensitive resin composition on one surface of the PET film. The thicknesses of the photosensitive layer at 10 spots were measured by using a measurement device (Main Body: Product Name “MH-15”, Measurement Stage: Product Name “MS-5C”), manufactured by NIKON CORPORATION, to obtain the average value of the thicknesses. The average value of the thicknesses of the photosensitive layer is shown in Table 1.

### <Evaluation>

### (Production of Stacked Body)

A copper clad laminate (manufactured by Showa Denko Materials Co., Ltd., Product Name “MCL-E-67”) in which a copper foil (Thickness: 12 μm) was stacked on both surfaces of a glass-fiber reinforced epoxy resin layer was washed with water. Subsequently, the copper clad laminate was washed with an acid and washed with water, and then, dried with an air flow. Next, the copper clad laminate was heated to 80° C., and then, the photosensitive element was stacked on the copper foil of the copper clad laminate. By using a heat roll at 110° C., the stacking was performed at a crimping pressure of 0.4 MPa and a roll rate of 1.0 m/minute. Accordingly, a stacked body in which the copper clad laminate, the photosensitive layer, and the PET film were stacked in this order was obtained.

### (Evaluation of Sensitivity)

A photo tool including a 41-stage step tablet with a concentration region of 0.00 to 2.00, a concentration step of 0.05, a tablet size of 20 mm×187 mm, and each step size of 3 mm×12 mm was placed on the PET film of the stacked body, as a negative mask. Next, the photosensitive layer was exposed with a parallel light exposure machine (manufactured by ORC MANUFACTURING CO., LTD., Product Name “EXM-1201”) using a high-pressure mercury lamp as a light source in an energy amount in which the number of remaining steps after developing the 41-stage step tablet was 14.0. On the basis of an exposure amount (Unit: mJ/cm²) in this case, a sensitivity (a photosensitivity) was evaluated. It is indicated that the sensitivity increases as the exposure amount decreases. Results are shown in Table 1.

### (Evaluation of Resolution)

A mask for evaluating a resolution, having a pattern in which (1) a square coil pattern with Line Width/Space Width of x/x (x: 10 to 100, Unit: μm) and (2) a dot pattern with a diameter of 10 to 100 μm were arranged into the shape of a grid, was placed on the PET film of the stacked body. After that, exposure was performed in an energy amount in which the number of remaining steps after developing the 41-stage step tablet was 14.0. After exposure, the PET film was peeled, and 1% by mass of a sodium carbonate aqueous solution at 30° C. was sprayed for a time period twice the shortest developing time (the shortest time required for an unexposed portion to be removed), and the unexposed portion was removed. Accordingly, a resist pattern was formed.

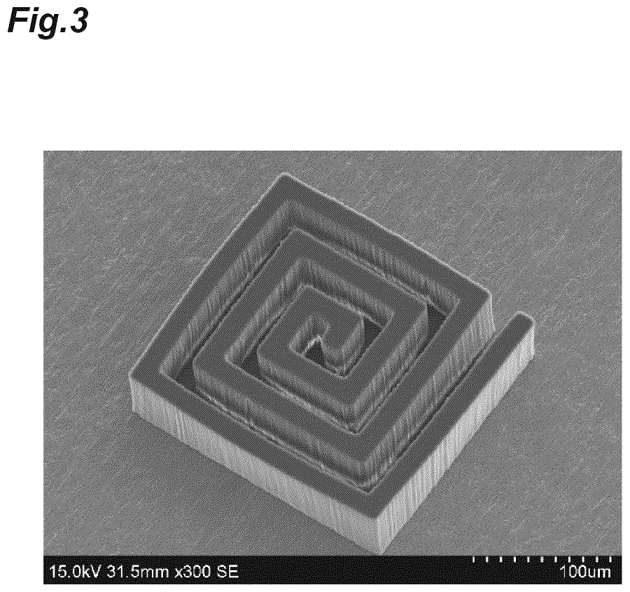

For (1) the square coil pattern, after the developing treatment, in the resist patterns in which a space portion (the unexposed portion) was completely removed, and a line portion (an exposed portion) was formed without causing crooking, chipping, and collapsing, the resolution (the square coil pattern) was evaluated with an optical microscope, on the basis of the smallest value of Line Width/Space Width. It is indicated that the resolution (the square coil pattern) increases as the numerical value decreases. In addition, a ratio of the thickness of the resist pattern to the resolution (Aspect Ratio: Thickness of Resist Pattern/Resolution) was calculated. Results are shown in Table 1. In addition, an electron microscopic picture of a square coil pattern (a pattern having the smallest Line Width/Space Width) formed by using the photosensitive element of Example 2 is illustrated in FIG. 3.

For (2) the dot pattern, after the developing treatment, the formed via pattern (via hole pattern) was observed and evaluated with an optical microscope. In the via patterns arranged into the shape of a grid, in which the entire surface was completely removed (opened), the resolution (the via pattern) was evaluated on the basis of the smallest value of the via pattern diameter. It is indicated that resolution (the via pattern) increases as the numerical value decreases. In addition, a ratio of the thickness of the resist pattern to the resolution (Aspect Ratio: Thickness of Resist Pattern/Resolution) was calculated. Results are shown in Table 1.

TABLE 1

| | | | | | Comparative | Comparative |
|---|---|---|---|---|---|---|
| | | Example 1 | Example 2 | Example 3 | Example 1 | Example 3 |
| Binder polymer (A) | A-1 | 56 | 56 | — | — | — |
| | A-2 | — | — | 56 | 56 | 56 |
| Photopolymerizable | FA-321M | 24 | 24 | 24 | 24 | 24 |
| compound (B) | UA-11 | 5 | 5 | 5 | 5 | 5 |
| | UA-13 | 5 | 5 | 5 | 5 | 5 |
| | FA-023M | 5 | 5 | 5 | 5 | 5 |
| | FA-318A | 5 | 5 | 5 | 5 | 5 |
| Photopolymerization | B-CIM | 3 | 3 | 3 | 3 | 3 |
| initiator (C) | | | | | | |
| Coumarin-based | Coumarin 102 | 0.2 | 0.02 | 0.02 | — | — |
| sensitizer (D) | | | | | | |
| Other components | EAB | — | — | — | 0.02 | 0.2 |
| | LCV | 0.35 | 0.35 | 0.35 | 0.35 | 0.35 |
| | Q-TBC-5P | 0.016 | 0.016 | 0.016 | 0.016 | 0.016 |
| | MKG | 0.008 | 0.008 | 0.008 | 0.008 | 0.008 |
| | SH-193 | 0.04 | 0.04 | 0.04 | 0.04 | 0.04 |
| Solvent | MAL | 5 | 5 | 5 | 5 | 5 |
| | TLS | 9 | 9 | 9 | 9 | 9 |
| | ACS | 5 | 5 | 5 | 5 | 5 |
| Thickness (μm) of photosensitive layer | | 60 | 60 | 60 | 60 | 60 |
| Sensitivity (mJ/cm²) | | 39 | 77 | 77 | 85 | 57 |
| Square coil pattern | Resolution (μm) | 20 | 18 | 22 | 24 | 32 |
| | Aspect ratio | 3.0 | 3.3 | 2.7 | 2.5 | 1.9 |
| Via pattern | Resolution (μm) | 35 | 35 | 40 | 45 | 50 |
| | Aspect ratio | 1.7 | 1.7 | 1.5 | 1.3 | 1.2 |

Reference Signs List

1: photosensitive element, 1a: photosensitive layer, 1b: support
(support film), 10: photosensitive layer, 10a: resist pattern, 20: base
material, 30: conductor layer, L: active ray.

1. A photosensitive element, comprising:
a support; and
a photosensitive layer formed on the support by using a photosensitive resin composition containing a binder polymer, a photopolymerizable compound, a photopolymerization initiator, and a coumarin-based sensitizer,
wherein a thickness of the photosensitive layer is 30 μm or more.

2. The photosensitive element according to claim 1,
wherein the binder polymer has benzyl (meth)acrylate as a monomer unit.

3. The photosensitive element according to claim 2,
wherein, in the binder polymer, a content of the benzyl (meth)acrylate is 10 to 60% by mass, on the basis of a total amount of the monomer unit configuring the binder polymer.

4. The photosensitive element according to claim 1,
wherein the binder polymer has styrene as a monomer unit.

5. The photosensitive element according to claim 4,
wherein, in the binder polymer, a content of the styrene is 10 to 50% by mass, on the basis of a total amount of the monomer unit configuring the binder polymer.

6. The photosensitive element according to claim 1,
wherein the binder polymer has alkyl (meth)acrylate as a monomer unit.

7. The photosensitive element according to claim 6,
wherein, in the binder polymer, a content of the alkyl (meth)acrylate is 5 to 40% by mass, on the basis of a total amount of the monomer unit configuring the binder polymer.

8. The photosensitive element according to claim 1,
wherein the binder polymer has a (meth)acrylic acid as a monomer unit.

9. The photosensitive element according to claim 8,
wherein, in the binder polymer, a content of the (meth)acrylic acid is 10 to 40% by mass, on the basis of a total amount of the monomer unit configuring the binder polymer.

10. The photosensitive element according to claim 1,
wherein a content of the coumarin-based sensitizer is 0.01 to 0.3 parts by mass, with respect to 100 parts by mass of a total amount of the binder polymer and the photopolymerizable compound.

11. The photosensitive element according to claim 1,
wherein the photopolymerizable compound includes (meth)acrylate having one polymerizable ethylenically unsaturated bond in molecules.

12. The photosensitive element according to claim 11,
wherein a content of the (meth)acrylate having one polymerizable ethylenically unsaturated bond in the molecules is 1 to 30% by mass, on the basis of a total amount of the photopolymerizable compound.

13. The photosensitive element according to claim 1,
wherein the photopolymerizable compound includes urethane (meth)acrylate.

14. The photosensitive element according to claim 1,
wherein the photopolymerization initiator includes at least one type selected from the group consisting of a hexaaryl biimidazole derivative and an acridine compound.

15. The photosensitive element according to claim 1,
wherein the thickness of the photosensitive layer is 75 μm or more.

16. The photosensitive element according to claim 1,
wherein the thickness of the photosensitive layer is greater than 100 μm.

17. The photosensitive element according to claim 1,
wherein the photosensitive element is for forming a resist pattern including a space portion with an aspect ratio of 1.3 or more.

18. The photosensitive element according to claim 1,
wherein the photosensitive element is for forming a conductive coil of an inductor.

19. The photosensitive element according to claim 1,
wherein the photosensitive element is for forming a copper pillar for semiconductor connection.

20. A method for forming a resist pattern, comprising:
a step of providing a photosensitive layer on a base material by using the photosensitive element according to claim 1;
a step of irradiating at least a part of the photosensitive layer with an active ray to form a photocured portion; and
a step of removing at least a part of the photosensitive layer other than the photocured portion to form a resist pattern.

21. The method for forming a resist pattern according to claim 20,
wherein the resist pattern includes a space portion with an aspect ratio of 1.3 or more.
